(19) United States
(12) Patent Application Publication
(10) Pub. No.: US 2014/0160467 A1
(43) Pub. Date: Jun. 12, 2014

(54) SYSTEM AND METHOD FOR CHARACTERIZING MATERIAL SHRINKAGE USING COHERENT ANTI-STOKES RAMAN SCATTERING (CARS) MICROSCOPY

(71) Applicant: Newport Corporation, Irvine, CA (US)

(72) Inventors: Tommaso Baldacchini, Irvine, CA (US); Ruben Zadoyan, Irvine, CA (US)

(21) Appl. No.: 14/182,019

(22) Filed: Feb. 17, 2014

Related U.S. Application Data
(63) Continuation of application No. PCT/US2011/048329, filed on Aug. 18, 2011.

(51) Int. Cl. G01N 21/65; G03F 7/20

(52) U.S. Cl. CPC G01N 21/65; G03F 7/20
USPC 356/72

(57) ABSTRACT

System and method are disclosed for measuring properties (e.g., shrinkage) of a photosensitive material (e.g., photoresist) while undergoing a defined photolithography process. The system includes a photolithography processing system adapted to perform a defined photolithography process of the photosensitive material, and a coherent anti-Stokes Raman scattering (CARS) microscopy system adapted to perform measurement of the properties of the photosensitive material. In another aspect, the CARS microscopy system is adapted to measure properties of the photosensitive material simultaneous with the defined photolithography process being performed on the photosensitive material by the photolithography processing system. In still another aspect, the CARS microscopy system is adapted to measure properties of the photosensitive material while the defined photolithography process on the photosensitive material is paused. Another system is adapted to perform similar measurements during the manufacturing of the photosensitive material.

### CROSS-REFERENCE TO RELATED APPLICATIONS

This application is a continuation of Patent Cooperation Treaty Patent Application No. PCT/US2011/48329, entitled “SYSTEM AND METHOD FOR CHARACTERIZING MATERIAL SHRINKAGE USING COHERENT ANTI-STOKES RAMAN SCATTERING (CARS) MICROSCOPY”, filed on Aug. 18, 2011 which is incorporated herein by reference.

### FIELD

This disclosure relates generally to in-situ material (e.g., photoresist) characterization, and in particular, to a system and method for characterizing material (e.g., photoresist) shrinkage using coherent anti-Stokes Raman scattering (CARS) microscopy.

### BACKGROUND

The manufacturing of microelectronic devices, such as integrated circuits (ICs) and circuits on printed circuit boards (PCBs), typically involve multiple steps. One such step that is ubiquitously used in the manufacture of microelectronic devices is photolithography. In photolithography, a material, such as a metal or dielectric deposited over a substrate or PCB, may be patterned using a mask containing a corresponding two-dimensional printed design.

More specifically, in photolithography, a photosensitive material, such as photoresist, is deposited over the material to be patterned. A mask, containing a printed two-dimensional design for the pattern, is placed over the photosensitive material. Then, the photosensitive material is exposed to defined radiation through the mask. The mask prevents certain portions of the photosensitive material from being exposed to the radiation, and allows other portions of the photosensitive material to be exposed to the radiation, in accordance with the pattern on the mask.

Based on the type of photosensitive material, the radiation-exposed portion may either be more susceptible (e.g., weakened) or resistive (e.g., strengthened) when subjected to a following developing process. For example, if the photosensitive material is weakened by the radiation, the material is referred to as positive photoresist. On the other hand, if the photosensitive material is strengthened by the radiation, the material is referred to as negative photoresist. The weakened portion of the photoresist may then be removed followed by etching or patterning of the underlying material, where the remaining (strengthened) portion of the photoresist operates to protect the underlying material from the etching or patterning process.

The accuracy in which the pattern on the mask is transferred to the material being patterned depends, at least in part, on the development of the photoresist. For instance, ideally, the portion of the photoresist exposed to the radiation should react substantially uniform and as specified in accordance with the radiation. Whereas, the unexposed portion should not react at all to the radiation. However, often this may not be the case. As a result, incomplete exposure of the radiation may occur in the portion designed to be exposed to the radiation, and unintended exposure may occur to the portion designed not to be exposed to the radiation. An example of a non-ideal development of a negative photoresist is given as follows.

FIG. 1A illustrates a cross-sectional view of an exemplary microelectronic circuit 100 at a particular stage of an exemplary photolithography process. The circuit 100 comprises a substrate (or PCB) 102, a material layer 104 disposed over the substrate 104, and a layer of negative photoresist 106 disposed over the material layer 104. During photolithography, a mask 108 is positioned over the negative photoresist 106. The mask 108 includes portions 108a that substantially block the radiation and includes portions 108b that substantially allows the radiation to pass through, in accordance with the pattern on the mask. Portions of the negative photoresist 106 directly underlying the transparent portions 108b of the mask are then subjected to radiation (e.g., ultraviolet (UV), deep UV (DUV), or other), as indicated by the arrows. The remaining portions of the negative photoresist 106 are not exposed to the radiation.

FIG. 1B illustrates a cross-sectional view of the exemplary microelectronic circuit 100 at a subsequent stage of the exemplary photolithography process. After being subjected to the radiation, the photoresist 106 includes portions 106b that are resistive (e.g., strengthened) to a following development process. This may be due to the radiation producing cross-linking of polymers in the exposed negative photoresist 106b. The remaining portions 106a of the negative photoresist 106 not exposed to the radiation are not strengthened, and thus are less resistive or susceptible to the following development process.

FIG. 1C illustrates a cross-sectional view of the exemplary microelectronic circuit 100 at another subsequent stage of the exemplary photolithography process. After the photoresist 106 has been exposed to the specified radiation, the circuit 100 undergoes a photoresist development process to remove the untreated or weaker portions 106b of the negative photoresist 106. Thus, what remains is the developed photoresist 106b which operates in a following etching process to protect the portion of the material layer 104 directly underlying the developed photoresist.

FIG. 1D illustrates a cross-sectional view of the exemplary microelectronic circuit 100 at another subsequent stage of the exemplary photolithography process. After development of the photoresist, the circuit 100 undergoes an etching process to remove the material layer 104 at portions not directly underlying the developed photoresist 106b. After this step, the developed photoresist 106b is removed, leaving behind the resulting patterned material 110.

FIG. 1E illustrates an expanded view of the developed photoresist 106b previously discussed. Ideally, all of the photoresist 106b directly underlying the transparent portion 108b of the mask 108 should uniformly react to the radiation to produce cross-linking of polymers so the entire portion is resistive to the following development process. However, sometimes this is not the case. Often, the photoresist 106b does not uniformly react to the radiation. As a result, during the removal of the unexposed portions 106a of the photoresist 106, some of the exposed portion 106b is also removed. This results in shrinkage in the resulting developed photoresist 106c as illustrated. This may lead to error in the patterning of the underlying material layer 104. For example, photo polymerization of commercial and custom made resins are most often followed by a reduction in volume. The material stress that originates from this phenomenon causes many difficulties in several applications because of either internal or interfacial defects.

Thus, in order to improve the photolithography process, it would be desirable to characterize the development of the photoresist, including shrinkage and other polymeric and structural transformation of the material. It would also be desirable to perform this characterization in-situ, as well as in real-time, during the manufacture of the microelectronic circuit.

### SUMMARY

An aspect of the disclosure relates to a system for measuring one or more properties (e.g., shrinkage) of a photosensitive material (e.g., photoresist), while the material is undergoing a photolithography process. The system comprises a photolithography processing system adapted to perform a defined photolithography process on the photosensitive material, and a coherent anti-Stokes Raman scattering (CARS) microscopy system adapted to perform the measurement of one or more properties of the photosensitive material. In another aspect, the CARS microscopy system is adapted to measure one or more properties of the photosensitive material simultaneous with the photolithography processing system performing the defined photolithography process on the photosensitive material. In still another aspect, the CARS microscopy system is adapted to measure the one or more properties of the photosensitive material while the photolithography processing system has paused or temporarily halted the defined photolithography process performed on the photosensitive material.

In another aspect of the disclosure, the system further comprises a scanning mechanism adapted to subject distinct portions of the photosensitive material to the measurement of the one or more properties performed by the CARS microscopy system. In one aspect, the scanning mechanism is adapted to move the photosensitive material. In another aspect, the scanning mechanism is adapted to steer an incident radiation beam at the photosensitive material. In still another aspect, the scanning mechanism is adapted to steer both a Stokes radiation beam and a pump radiation beam at the photosensitive material.

In another aspect of the disclosure, the CARS microscopy system comprises a Stokes beam source adapted to generate a Stokes radiation beam with a frequency ω_{S}, and a pump radiation beam adapted to generate a pump radiation beam with a frequency ω_{P}. In one aspect, the CARS microscopy system is adapted to direct the Stokes radiation beam and the pump radiation beam to substantially the same region on the photosensitive material. In still another aspect, the CARS microscopy system is adapted to combine the Stokes radiation beam and the pump radiation beam to generate a coherent radiation with a frequency of 2ω_{P}−ω_{S}.

In another aspect, the CARS microscopy system comprises at least two radiation sources adapted to generate a coherent radiation beam upon the photosensitive material, and a detector adapted to detect radiation emitted by the photosensitive material in response to the incident radiation beams. In one aspect, the emitted radiation by the photosensitive material provides information regarding the one or more properties of the photosensitive material. In still another aspect, the one or more properties of the photosensitive material comprise a degree of cross-linking of polymers in the photosensitive material. In yet another aspect, the one or more properties of the photosensitive material comprise a degree of polymer weakening or scission in the photosensitive material.

Additionally, in another aspect of the disclosure, the photosensitive material comprises a photoresist. In another aspect, the photoresist comprises a negative photoresist. In still another aspect, the photoresist comprises a positive photoresist. Other aspects relate to a method of performing the measurement of the one or more properties of the photosensitive material. Also, other aspects relate to a system for measuring one or more properties of a photosensitive material while the material is being manufactured.

Other aspects, advantages and novel features of the disclosure will become apparent from the following detailed description of the invention when considered in conjunction with the accompanying drawings.

### BRIEF DESCRIPTION OF THE DRAWINGS

FIGS. 1A-1E illustrate a circuit at various stages of an exemplary photolithography process.

FIG. 2 illustrates a block diagram of an exemplary in-situ photoresist characterization system in accordance with an embodiment of the disclosure.

FIG. 3 illustrates a block diagram of another exemplary in-situ photoresist characterization system in accordance with another embodiment of the disclosure.

FIG. 4 illustrates a block diagram of another exemplary in-situ photoresist characterization system in accordance with another embodiment of the disclosure.

FIG. 5 illustrates a block diagram of an exemplary in-situ photoresist characterization system in accordance with another aspect of the disclosure.

FIG. 6 illustrates a flow diagram of an exemplary method of characterizing photoresist in-situ while undergoing a process in accordance with another aspect of the disclosure.

FIG. 7 illustrates a flow diagram of another exemplary method of characterizing photoresist in-situ while undergoing a process in accordance with another aspect of the disclosure.

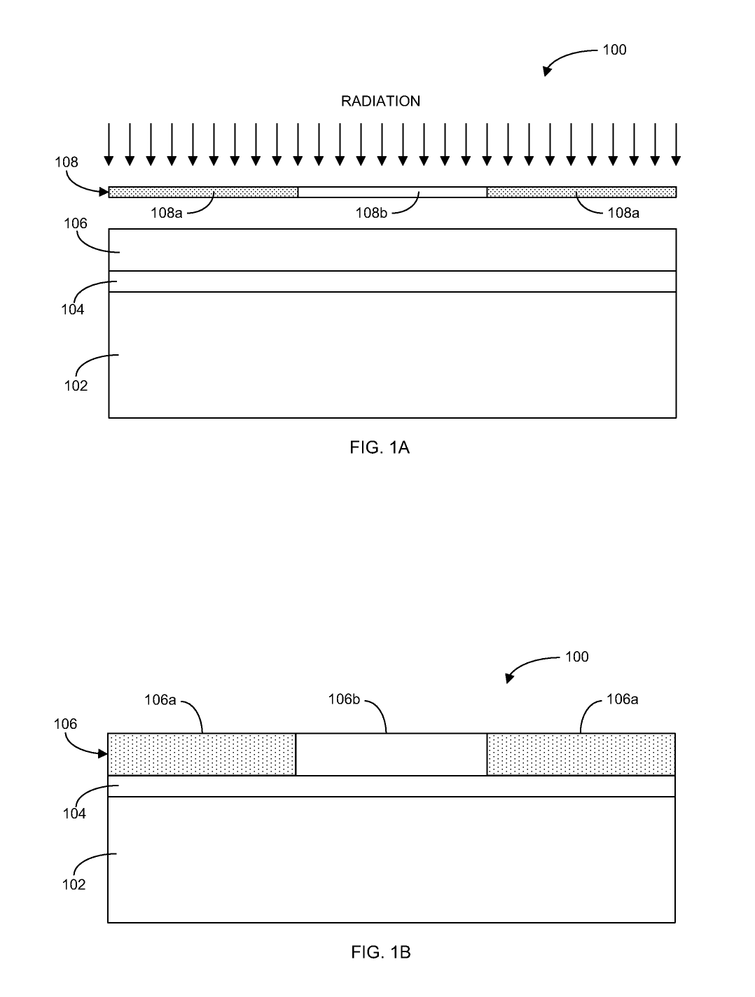

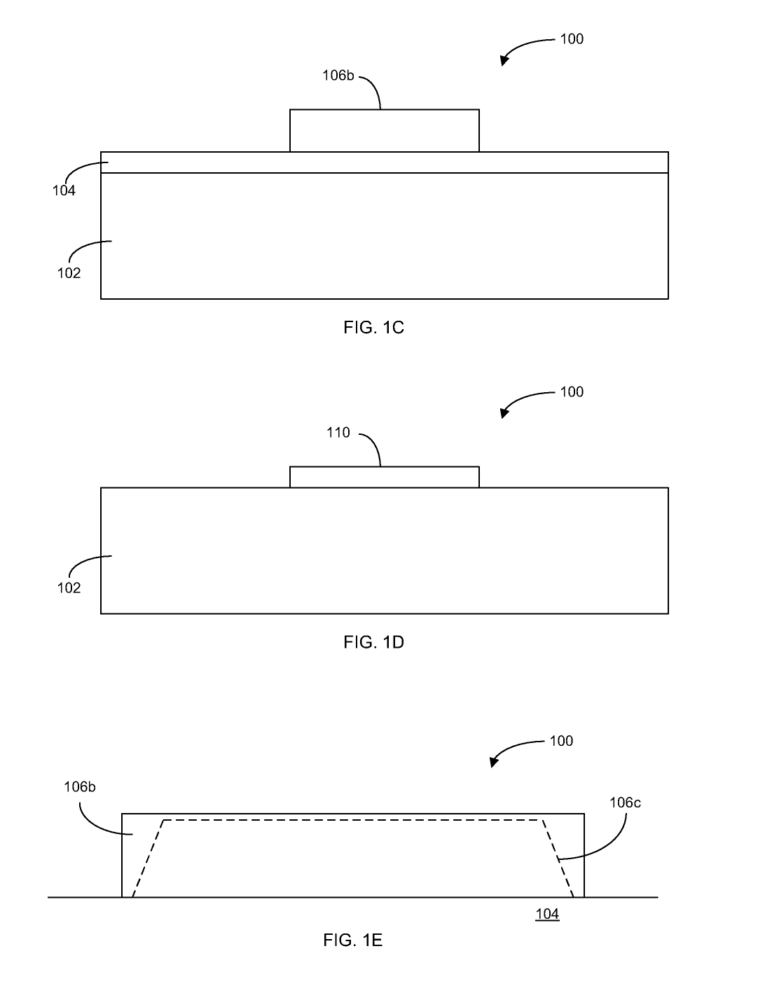

### DETAILED DESCRIPTION OF THE EXEMPLARY EMBODIMENTS

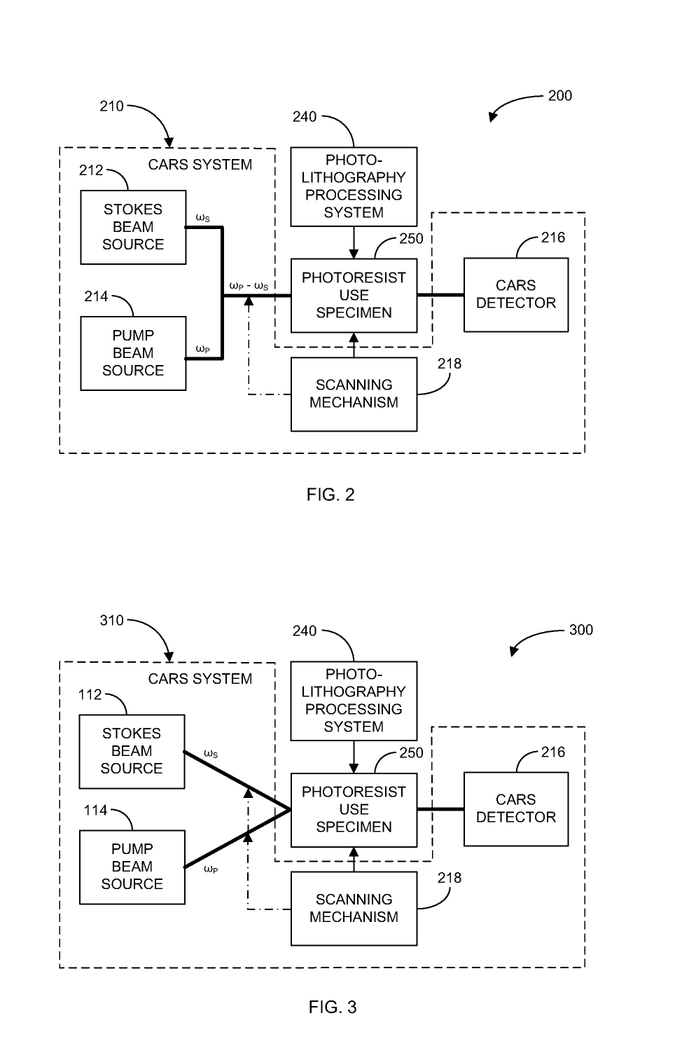

FIG. 2 illustrates a block diagram of an exemplary in-situ material characterization system 200 in accordance with an embodiment of the disclosure. In summary, the in-situ material characterization system 200 uses a coherent anti-Stokes Raman scattering (CARS) microscopy system to measure one or more properties of a photosensitive material (e.g., a photoresist) undergoing a photolithography process. For instance, the CARS system is able to detect the formation of cross-linking in polymers in, for example, negative photoresist, while being exposed to the specified radiation pursuant to the photolithography process. Similarly, the CARS system is able to detect polymer weakening or scission in, for example, positive photoresist, while being exposed to the specified radiation pursuant to the photolithography process. Thus, by monitoring the photoresist while it is undergoing a photolithography process using a CARS system, for example, shrinkage and/or other properties of the photoresist may be readily observed. This would be useful in improving and/or optimizing processes for development of photosensitive material, such as positive or negative photoresist.

More specifically, the in-situ material characterization system 200 comprises a CARS microscopy system 210 configured for in-situ measuring of one or more properties of a photoresist specimen 250 undergoing a particular photolithography process performed by a photolithography processing system 240. The CARS microscopy system 210, in turn, comprises a Stokes beam source 212, a pump beam source 214, a detector 216, and a scanning mechanism 218. The Stokes beam source 212 generates a Stokes radiation beam with a frequency ω_{S}. The pump beam source 214 generates a pump radiation beam with a frequency ω_{P}. The Stokes and pump beams may be combined (e.g., one modulates the other) within the CARS system 210 to generate an incident radiation beam with a frequency 2ω_{P}−ω_{S}.

By adjusting the difference between the pump beam frequency and the Stokes beam frequency, the incident radiation signal may be tuned to substantially the frequency of a Raman active vibrational mode of at least a portion the photoresist specimen 250. The excitation beams interact with the photoresist specimen 250, generating a coherent signal at a frequency that is higher than both the pump and Stokes frequencies. The shorter wavelength pulse is detected by the detector 216 to ascertain information about one or more properties of the photoresist specimen 250. The scanning mechanism 218 is adapted to move the wafer, PCB, or other element containing the photoresist specimen 250 relative to the incident radiation beam to allow the beam to interact with different portions or regions of the photoresist specimen. The scanning mechanism 218 may perform this by actually moving the photoresist specimen 250 (e.g., by moving the structure (e.g., a stage) that supports the photoresist specimen). Alternatively, or in addition to, the scanning mechanism 218 may be able to steer the incident radiation beam.

By spatially scanning the incident radiation beam, a chemical-specific three-dimensional image of the photoresist specimen 250 may be ascertained, which describes the concentration or density of the excited molecular oscillators within the photoresist specimen. The detected signal is proportional to the square of the third-order susceptibility, and therefore, strongly dependent on the number of vibrational oscillators. Thus, discontinuities in the detected signal are a direct consequence of polymer density variations in the photoresist specimen 250. Thus, while the photoresist specimen 250 is undergoing the process performed by the photolithography processing system 240, the CARS system 210 is able to generate a three-dimensional image of the polymer cross-link density of the photoresist specimen, which is useful for many applications, such as optimizing the photolithography processing of the photoresist specimen, characterizing the structure and features of the photoresist specimen, such as photoresist shrinkage, detecting defects in the photoresist specimen, ascertaining uniformity and non-uniformity of the photoresist specimen, and others. Again, this would be helpful in tuning the photolithography process in order to achieve optimal photoresist development.

FIG. 3 illustrates a block diagram of another exemplary in-situ material characterization system 300 in accordance with another embodiment of the disclosure. The in-situ material characterization system 300 is similar to that of system 200, and includes many of the same elements as noted by the same reference numbers. A difference between the in-situ material characterization system 300 and system 200 is that both the Stokes radiation beam and the pump radiation beam are focused upon the photoresist specimen 250. Thus, the incident radiation beam is generated at substantially the photoresist specimen 250. In this case, the scanning mechanism 218 may steer the Stokes beam and pump beam individually, although in a manner that they both are focused at substantially the same region of the photoresist specimen 250.

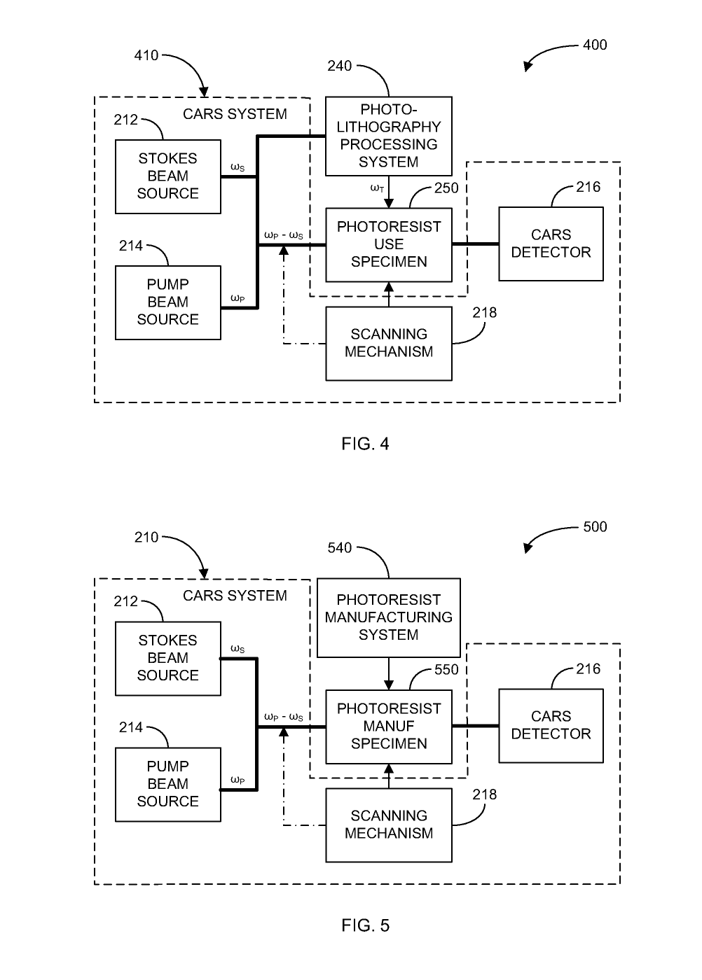

FIG. 4 illustrates a block diagram of another exemplary material characterization system 400 in accordance with another aspect of the disclosure. The material characterization system 400 is similar to the system 200 previously described, and includes many of the same elements as noted by the same reference numbers. The material characterization system 400 differs with respect to system 200 in that it includes a CARS system 410 in which a portion of the pump radiation beam is sent to the photolithography processing system 240. The photolithography system 240 generates a radiation beam ω_{T} that is derived at least in part from the pump radiation beam ω_{P}. The photoresist specimen 250 is subjected to the photolithography radiation beam ω_{T} to induce polymer cross-linking in a negative photoresist specimen, or polymer weakening or scission in a positive photoresist specimen. In such a system 400, the CARS system 410 is able to monitor in “real-time” the photoresist specimen 250, while it is undergoing the photolithography process performed by the photolithography processing system 240.

FIG. 5 illustrates a block diagram of another exemplary material characterization system 500 in accordance with another aspect of the disclosure. The material characterization system 500 is similar to the system 200 previously described, and includes many of the same elements as noted by the same reference numbers. The material characterization system 500 differs with respect to system 200 in that the system 500 is configured to characterize photosensitive material (e.g., photoresist) while it is being manufactured, as opposed to being used as in the previous embodiments. Accordingly, the material characterization system 500 comprises a photoresist manufacturing system 540 performing a process of manufacturing a photoresist specimen 550.

The manufacture of photoresist 500 typically includes precisely mixing several different elements. For instance, photoresist is typically a mixture of several elements, such as monomers, oligomers, eluents, photo sensitizers, and one or more additives. Photoresists either polymerize or de-polymerize (e.g., photosolubilize) when exposed to a particular radiation. For instance, negative photoresists typically include methacrylate monomers and olygomers, which are generally not chemically bonded together. Upon exposure to a particular radiation, the polymers in negative photoresist undergo cross-linking. Positive photoresists, on the other hand, typically include phenol-formaldehyde type molecule such as in novolak. Upon exposure to a particular radiation, the photoresist polymers weaken (e.g., photosolubilization).

The solvent element in photoresists allow them to be in a liquid form in order to facilitate deposition of the photoresist by spin-coating. The solvent used in negative photoresist typically includes tolune, xylene, and halogenated aliphatic hydrocarbons. On the other hand, the solvent used in positive photoresist, for instance, typically include organic solvents, such as 2-Ethoxyethanol acetate, bis(2-methoxyethyl) ether, and cyclohexanone.

The photo sensitizer element is used for controlling the polymer reactions when exposed to a particular radiation. For example, photo sensitizer may be used to broaden or narrow the response of the photoresist to the wavelength of the radiation. The photo sensitize used in negative photoresist typically includes bis-azide sensitizers. Whereas, the photo sensitize used in positive photoresist typically includes diazonaphthoquinones. One or more additives may be employed in photoresist to perform specific functions, such as to increase photo absorption by the photoresist, control light spreading within the photoresist, and/or improve adhesion of the photoresist to specified surfaces.

Again, as discussed above, while any of these elements are mixed together to form the photoresist, the CARS system 210 may take measurements of the photoresist material 550. These measurement may be taken in-situ and/or in real-time as further discussed below. The CARS system 500 provides measurements of the polymerization of the photoresist, which may be helpful in achieving a desired mixture or composition for the photoresist.

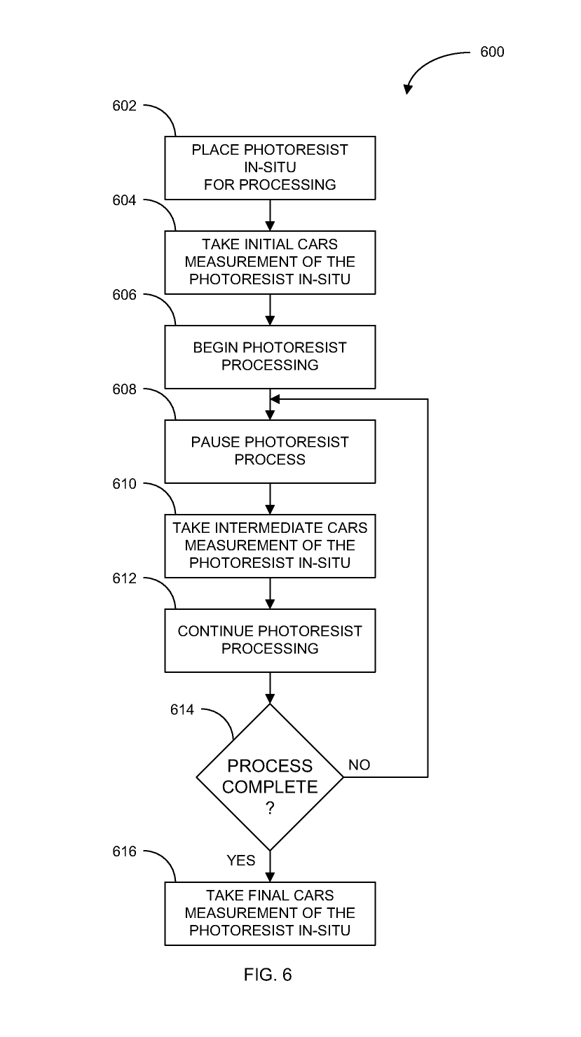

FIG. 6 illustrates a flow diagram of an exemplary method 600 of characterizing a photoresist specimen in-situ, while undergoing a photolithography or manufacturing process in accordance with another aspect of the disclosure. In this example, the processing of the photoresist specimen is paused or temporarily halted one or more times in order to perform one or more CARS measurements on the specimen, respectively.

More specifically, according to the method 600, the photoresist specimen is placed in-situ for processing (block 602). Then, an initial CARS measurement of the photoresist specimen may be taken in order to characterize the specimen at an early stage of the process (block 604). Then, the processing of the photoresist specimen is begun or continued (block 606). The processing of the photoresist specimen may be paused prior to completion of the process to take a measurement of the specimen (block 608). While the process is paused, a CARS measurement of the photoresist specimen in-situ is taken (block 610). After the measurement, the process is resumed (block 612). Prior to completion of the process, additional intermediate CARS measurement of the photoresist specimen may be taken. Thus, in this regards, if the process is not complete pursuant to block 614, the operations 608 through 614 may be repeated to obtain additional CARS measurements of the photoresist specimen as desired. When the process is complete pursuant to block 614, a final CARS measurement of the photoresist specimen may be taken (block 616).

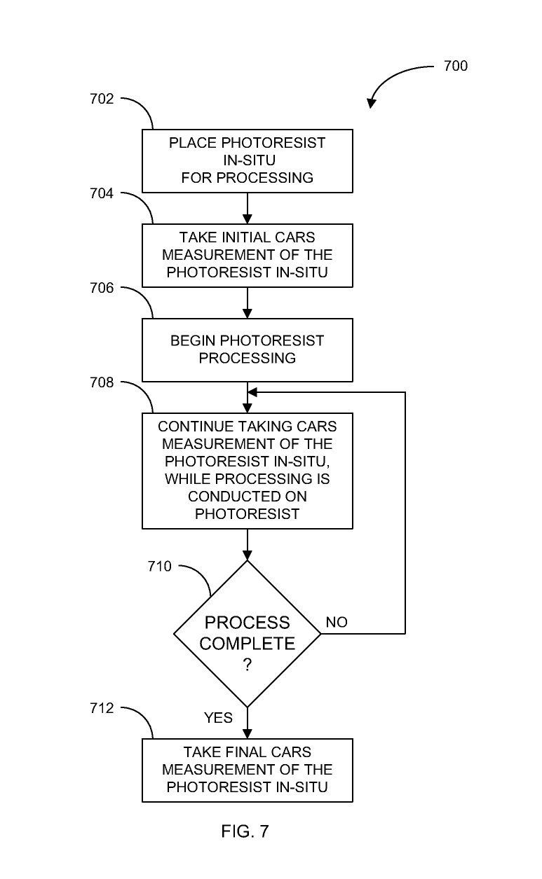

FIG. 7 illustrates a flow diagram of another exemplary method 700 of characterizing a photoresist specimen in-situ undergoing a process in accordance with another aspect of the disclosure. In the previous example, although the photoresist specimen was in-situ, the process being performed on the specimen was paused or temporarily halted for the purpose of taking a CARS measurement of the specimen. In this example, the process is not halted, and the CARS measurement of the photoresist specimen is taken while the process is being performed on the specimen.

More specifically, according to the method 700, the photoresist specimen is placed in-situ for processing (block 702). Then, an initial CARS measurement of the photoresist specimen may be taken in order to characterize the specimen at an early stage of the process (block 704). Then, the processing of the photoresist specimen is begun or continued (block 706). The CARS measurement of the photoresist specimen may be taken in a continuous, periodic, or in another manner, while the specimen is undergoing the defined process (block 708). Prior to completion of the process pursuant to block 710, additional CARS measurements of the photoresist specimen may be taken while the specimen is being processed (block 708). When the process is complete as determined in block 710, a final CARS measurement of the photoresist specimen may be taken (block 712).

While the invention has been described in connection with various embodiments, it will be understood that the invention is capable of further modifications. This application is intended to cover any variations, uses or adaptation of the invention following, in general, the principles of the invention, and including such departures from the present disclosure as come within the known and customary practice within the art to which the invention pertains.

What is claimed is:

1. A system for measuring one or more properties of a photosensitive material, comprising:
a photolithography processing system adapted to perform a defined photolithography process on the photosensitive material; and
a coherent anti-Stokes Raman scattering (CARS) microscopy system adapted to perform a measurement of the one or more properties of the photosensitive material.

2. The system of claim 1, wherein the CARS microscopy system is adapted to perform the measurement of the one or more properties of the photosensitive material simultaneous with the photolithography processing system performing the defined photolithography process on the photosensitive material.

3. The system of claim 1, wherein the photolithography processing system is adapted to pause the defined photolithography process being performed on the photosensitive material, and wherein the CARS microscopy system is adapted to perform the measurement of the one or more properties of the photosensitive material while the photolithography processing system has paused the defined photolithography process performed on the photosensitive material.

4. The system of claim 1, further comprising a scanning mechanism adapted to subject distinct portions of the photosensitive material to the measurement performed by the CARS microscopy system.

5. The system of claim 4, wherein the scanning mechanism is adapted to move the photosensitive material.

6. The system of claim 4, wherein the CARS system is adapted to generate an incident radiation beam directed at the photosensitive material, and wherein the scanning mechanism is adapted to steer the incident radiation beam.

7. The system of claim 4, wherein the CARS system comprises:
a Stokes beam source adapted to generate a Stokes radiation beam directed at the specimen; and
a pump beam source adapted to generate a pump radiation beam directed at the specimen;
wherein the scanning mechanism is adapted to steer the Stokes and pump radiation beams.

8. The system of claim 1, wherein the CARS microscopy system comprises:
a Stokes beam source adapted to generate a Stokes radiation beam with a frequency ω_{S}; and
a pump beam source adapted to generate a pump radiation beam with a frequency ω_{P}.

9. The system of claim 8, wherein the CARS microscopy system is adapted to direct the Stokes radiation beam and the pump radiation beam to substantially the same region of the photosensitive material.

10. The system of claim 8, wherein the CARS microscopy system is adapted to combine the Stokes radiation beam and the pump radiation beam to generate an incident radiation beam directed at the photosensitive material, wherein the incident radiation beam has a frequency of 2ω_{P}−ω_{S}.

11. The system of claim 1, wherein the CARS microscopy system comprises:
at least one radiation beam source adapted to generate an incident radiation beam upon the photosensitive material; and
a detector adapted to detect radiation emitted by the photosensitive material in response to the incident radiation beam.

12. The system of claim 11, wherein the emitted radiation by the photosensitive material provides information regarding the one or more properties of the photosensitive material.

13. The system of claim 12, wherein the one or more properties of the photosensitive material comprises a degree of cross-linking of polymers in the photosensitive material.

14. The system of claim 12, wherein the one or more properties of the photosensitive comprises a degree of polymer weakening or scission in the photosensitive material.

15. The system of claim 1, wherein the photosensitive material comprises a photoresist.

16. The system of claim 15, wherein the photoresist comprises a negative photoresist.

17. A method of measuring one or more properties of a photosensitive material while undergoing a defined photolithography process, comprising:
performing the defined photolithography process on the photosensitive material; and
measuring the one or more properties of the photosensitive material using coherent anti-Stokes Raman scattering (CARS) microscopy.

18. The method of claim 17, wherein measuring the one or more properties of the photosensitive material comprises measuring the one or more properties of the photosensitive material simultaneously with the defined photolithography process being performed on the photosensitive material.

19. The method of claim 17, further comprising pausing the defined photolithography process performed on the photosensitive material, wherein measuring the one or more properties of the photosensitive material is performed while the defined photolithography process on the photosensitive material is paused.

20. A system for measuring one or more properties of a photosensitive material while the photosensitive material is being manufactured, comprising:
a photosensitive material manufacturing system adapted to manufacture the photosensitive material; and
a coherent anti-Stokes Raman scattering (CARS) microscopy system adapted to perform a measurement of the one or more properties of the photosensitive material while the photosensitive material is being manufactured by the photosensitive material manufacturing system.
